(19) United States
(12) Patent Application Publication
(10) Pub. No.: US 2009/0009224 A1
(43) Pub. Date: Jan. 8, 2009

(54) Multiphase DLL using 3-edge phase detector for wide-range operation

(76) Inventors: Gyh-Bin Wang, Hsinchu (TW); Ying-Chieh Huang, Hsinchu (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 11/976,631

(22) Filed: Oct. 26, 2007

(30) Foreign Application Priority Data
Jul. 6, 2007 (TW) 96124803

(51) Int. Cl. H03L 7/06

(52) U.S. Cl. 327/158

(57) ABSTRACT

The invention discloses a new architecture of multiphase delay-locked loop (DLL) with innovative 3-edge phase detector (3-edge PD), which compares the VCDL's first delay interval and the last delay interval to send an Up pulse or a Dn pulse to adjust the interval among those delay clock phases. The DLL may achieve both wide-range operation and multiple clock phase generation, and is also immune to multi-selection problem.

### BACKGROUND OF THE INVENTION

1. Field of the Invention

The present invention relates to a multiphase Delay-Lock Loop (DLL), and more particularly, to a multiphase DLL for Wide-Range Operation.

2. Description of the Prior Art

Along with the continuous innovative development of the Complementary metal-oxide-semiconductor (CMOS), the processing speed and the circuit density of the integrated circuit (IC) increase continuously. Therefore, the synchronous processing between modules become an important issue, and so as to form a bottleneck for the development of IC.

Presently, the high-level circuit has a strong demand for the system clock signal source with high speed and quality. Nevertheless, the propagation delay of the clock driver or the phase difference will easily cause problems when the system clock signal source is operated in high speed, and so as to affect the chip reliability and the system performance. Accordingly, the design of the high-level circuit, such as a microprocessor, a real-time system or a data communication device, often needs to add a Phase-Locked Loop (PLL) with low voltage, high frequency and low jitter to serve as an auxiliary to correct the characteristic of the input clock signal source.

The CMOS PLL and the Delay-Lock Loop (DLL) are designed to solve the synchronous problem of the circuit clock, and the DLL is more stable than the PLL because of the structural difference. Further, the DLL seldom uses capacitors. Accordingly, there are more and more applications, such as the circuits of the clock recovery and the local oscillator, utilize the DLL to replace the PLL because the DLL is easy to design and stable recently. Additionally, the signal jitter of the DLL is not obvious. Because the noise in the Voltage-Controlled Delay Line (VCDL) will not accumulate after several clock cycles, such that the DLL is an ideal circuit unit for the clock synchronization processing and is suitable for applying for the radio frequency synthetic circuit and the high-speed serial connection.

FIG. 1 is a schematic diagram of a conventional DLL structure. The VCDL 11 receives a reference clock (Ref-Clk) signal, and then output several signals with phase delay. The output signals feedback to the phase detector (PD) 12, the charge pump (CP) 13 and the Loop Filter (LF) 14. The operation theory of the DLL is utilizing a delay element to automatically generate plural delay clock (DLL-Clk) signals with fixed phase difference according to the external input reference clock (Ref-Clk) signals, then orderly passing these DLL-Clk signals through functional circuit and then comparing with the original Ref-Clk signals to check if they are synchronous. Thus, there will be a DLL-Clk signal, which phase difference is small enough to be accepted as a locked DLL-Clk signal to accomplish the DLL process, to be selected through the selection of the control circuit.

FIG. 2A is a schematic diagram to show the condition that a DLL-Clk signal leads a Ref-Clk signal in a clock range AA′, these two signals can be synchronous as shown in FIG. 2B after the DLL operation. FIG. 3A is a schematic diagram to show the condition that a DLL-Clk signal lags a Ref-Clk signal in a clock range BB′, these two signals can be synchronous as shown in FIG. 3B after the DLL operation. However, the calibration range of the DLL for the signal deviation is AA′ to BB′, the vague multi-locking problem will be produced if the rising edge of the signal is not within this range.

The inequalities to be immune to multi-selection are shown in (1.1) and (1.2).

0.5×T_{CLK}<T_{VCDL}(min)<T_{CLK} (1.1)

T_{CLK}<T_{VCDL}(max)<1.5×T_{CLK} (1.2)

For example, 20 ns<T_{CLK}<40 ns is obtained from (1.1) and 26.7 ns<T_{CLK}<40 ns is obtained from (1.2) if T_{VCDL}(max)=40 ns. Accordingly, it can be understood from the aforementioned inequalities that the operational delay range of the T_{CLK} for the conventional DLL structure is limited.

### SUMMARY OF THE INVENTION

In order to solve the aforementioned problem, one object of the present invention is to provide a multiphase DLL for wide-range operation, which has a 3-edge Phase Detector (PD) to receive the reference, small delay and large delay clock signals, and then obtains a phase difference between the up signal (Up) and the down signal (Dn) by comparing three clock signals to adjust a control voltage for dynamically adjusting the delay time through the voltage control of the Voltage Control Delay Line (VCDL). The phase of the delay clock signal is changed, and the clock cycle time equally distributed to all delay clock signals, such that the operation range of the delay time is wider.

Another object of the present invention is to provide a 3-edge PD that uses two comparison circuits to respectively compare the reference clock signal, the final output Dn of the small delay clock signal and the final output Up of the large delay clock signal. Finally, the Dn and Up are transmitted to a CP.

Another object of the present invention is to provide a method to lock clock for a multiphase DLL with wide-range operation, which adjusts the delay signals in the VCDL to make the starting time of each delay signal averagely fall into a reference clock cycle and so as to avoid the vague multi-locking problem.

To achieve the purposes mentioned above, one embodiment of the present invention is to provide a multiphase DLL for wide-range operation, which includes: a VCDL to receive a reference clock signal to generate several delay clock signals, wherein the delay clock signals include a first delay clock signal and a second delay clock signal; a 3-edge PD to generate a set of pulse signals according to the reference clock signal, the first delay clock signal and the second delay clock signal; a CP to receive the pulse signals and output a current control signal; and an Loop Filter (LF) to receive the current control signal and output a control voltage, wherein a delay time is adjusted by the VCDL according to the control voltage.

Additionally, a 3-edge PD that is used to increase the operation range of the clock width according to one embodiment of the present invention, wherein the 3-edge PD receives a reference clock signal, a first delay clock signal and a second delay clock signal, and finally output a set of pulse signals.

Furthermore, a method to lock clock for a multiphase DLL with wide-range operation, which includes: setting a minimum delay time among a plurality of delay signals existed in the VCDL and arranged according to the time order to make the delay signals have the same delay time between each other, wherein a time interval between a first delay signal and a starting edge of a clock cycle is T1, and a time interval between a second delay signal and a starting edge of a clock cycle is Tn; comparing T1 and Tn to adjust the delay time and so as to make the delay signals fall into a reference clock cycle; increasing the delay time to make the delay signals have the same delay time between each other and so as to make the delay signals fall into a reference clock cycle if T1<Tn; and decreasing the delay time to make the delay signals have the same delay time between each other and so as to make the delay signals fall into a reference clock cycle if T1>Tn.

### BRIEF DESCRIPTION OF THE DRAWINGS

The foregoing aspects and many of the accompanying advantages of this invention will become more readily appreciated as the same becomes better understood by reference to the following detailed description when taken in conjunction with the accompanying drawings, wherein:

FIG. 1 is a schematic diagram of a conventional DLL structure;

FIG. 2A and FIG. 2B are schematic diagrams to show the condition that a DLL-Clk signal leads a Ref-Clk signal in a clock range AA′ for a conventional DLL;

FIG. 3A and FIG. 3B are schematic diagrams to show the condition that a DLL-Clk signal lags a Ref-Clk signal in a clock range BB′ for a conventional DLL;

FIG. 4 is a structural schematic diagram to demonstrate a multiphase DLL for wide-range operation according to one embodiment of the present invention;

FIG. 5A is a waveform schematic diagram to demonstrate a starting clock signal according to one embodiment of the present invention;

FIG. 5B is a waveform schematic diagram to demonstrate a clock signal after adjusting according to one embodiment of the present invention;

FIG. 6A and FIG. 6B are structural schematic diagrams to demonstrate a 3-edge PD according to one embodiment of the present invention;

FIG. 7A and FIG. 7B are schematic diagrams to relatively demonstrate the operational schematic diagrams to demonstrate the clock signals corresponding to 6A and FIG. 6B;

FIG. 8 is a schematic diagram to demonstrate a method to lock clock for a multiphase DLL according to one embodiment of the present invention; and

FIG. 9a to FIG. 9f are schematic diagrams to demonstrate the mechanism for avoiding multi-locking according to one embodiment of the present invention.

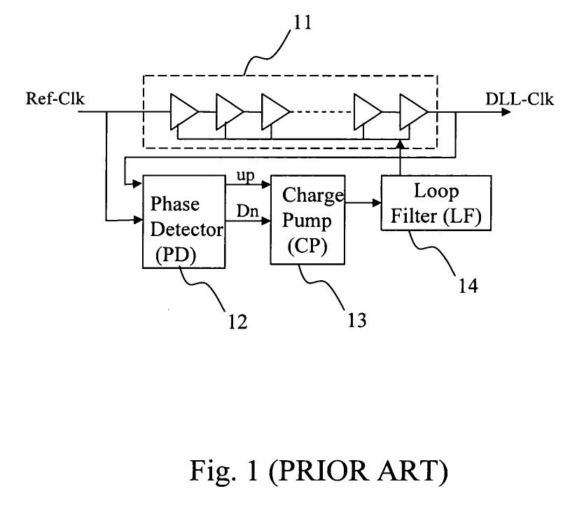

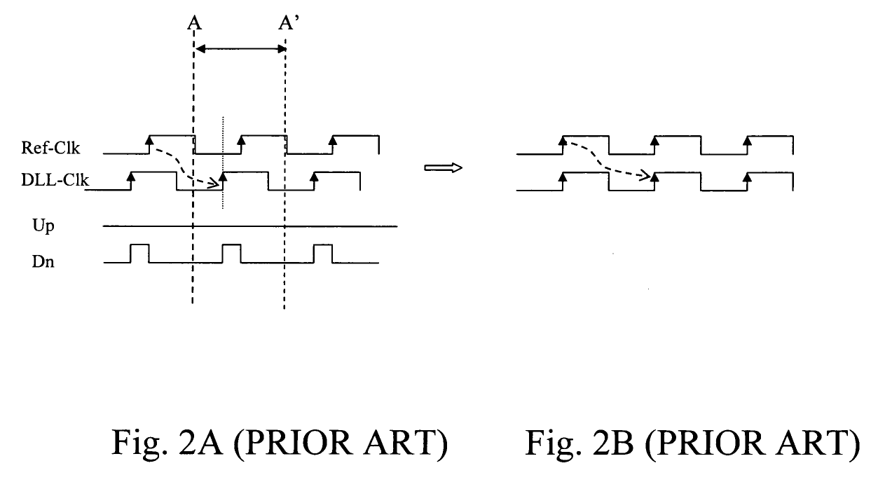

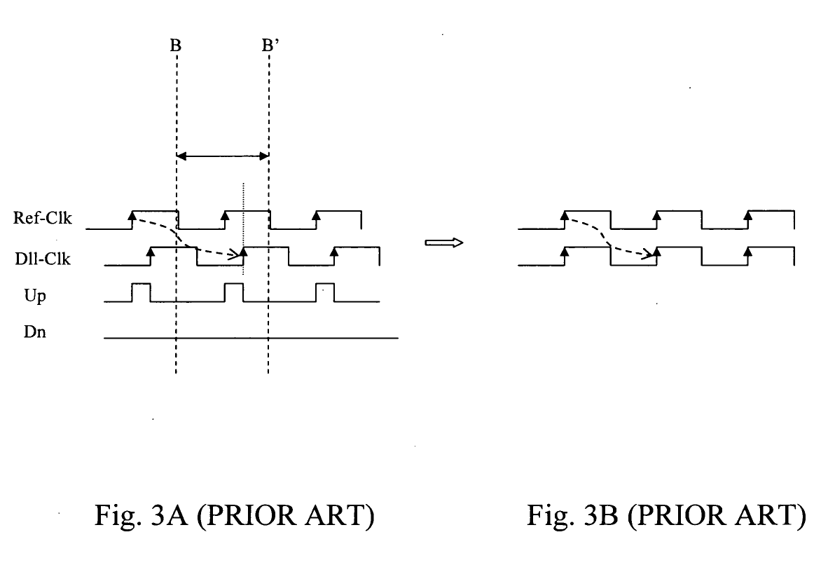

### DESCRIPTION OF THE PREFERRED EMBODIMENT

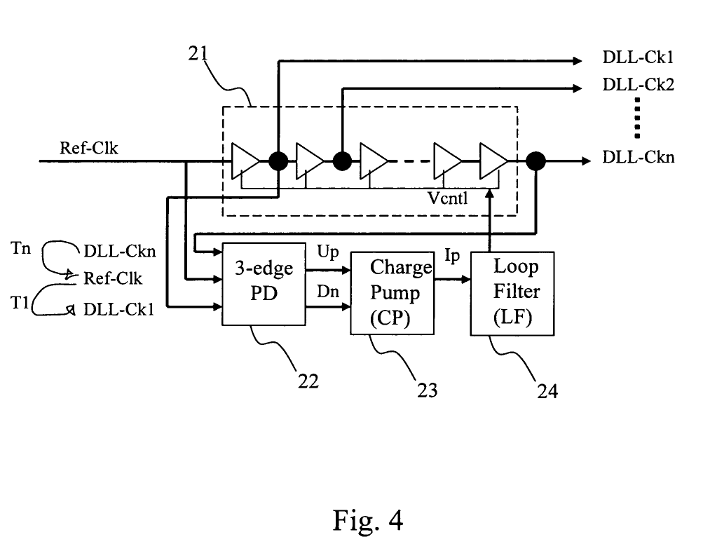

FIG. 4 is a structural schematic diagram to demonstrate a multiphase DLL for wide-range operation according to one embodiment of the present invention. In this embodiment, a VCDL 21 includes several sequentially connected delay elements to receive a reference signal Ref-Clk and output one to N delay clock signals DLL-Ck1, DLL-Ck2, . . . DLL-Ckn. Wherein the first delay clock signal is outputted from the first delay element and the second delay clock signal is outputted from the Nth delay element, and the first delay clock signal DLL-Ck1 and the Nth delay clock signal DLL-Ckn feedback to a 3-edge PD 22. Further, the Ref-Clk is also input to the 3-edge PD 22, thus the 3-edge PD 22 receives 3 input signals and then output a set of pulse signals which includes a down signal Dn and an up signal Up after processing.

In one embodiment, the processing way of the 3-edge PD 22 is comparing the first DLL-Ck1 and the last DLL-Ckn to decide a lead or lag phase difference, and finally generate an Up or Dn signal having the same width with the phase difference.

Next, the information of the frequency difference between the Up and Dn signals is transmitted to a CP 23 succeeded after the 3-edge PD 22 to serve as a reference and control the CP 23 and so as to generate a current Ip for charging or discharging a capacitor (not shown in the figure) in the succeeding LF 24, which means increasing or decreasing the voltage value of the capacitor in the LF 24. The LF 24 will filter out the high-frequency noise produced in the 3-edge PD 22 and the CP 23 and generate a control voltage Vcntl. The Vcntl can adjust the delay time (T_{VCDL}) of the VCDL 21 through the VCDL 21 and change the phase of the internal clock, and then feedback to the 3-edge PD 22 to start a comparison action of next cycle. In one embodiment, the LF 24 is a capacitor.

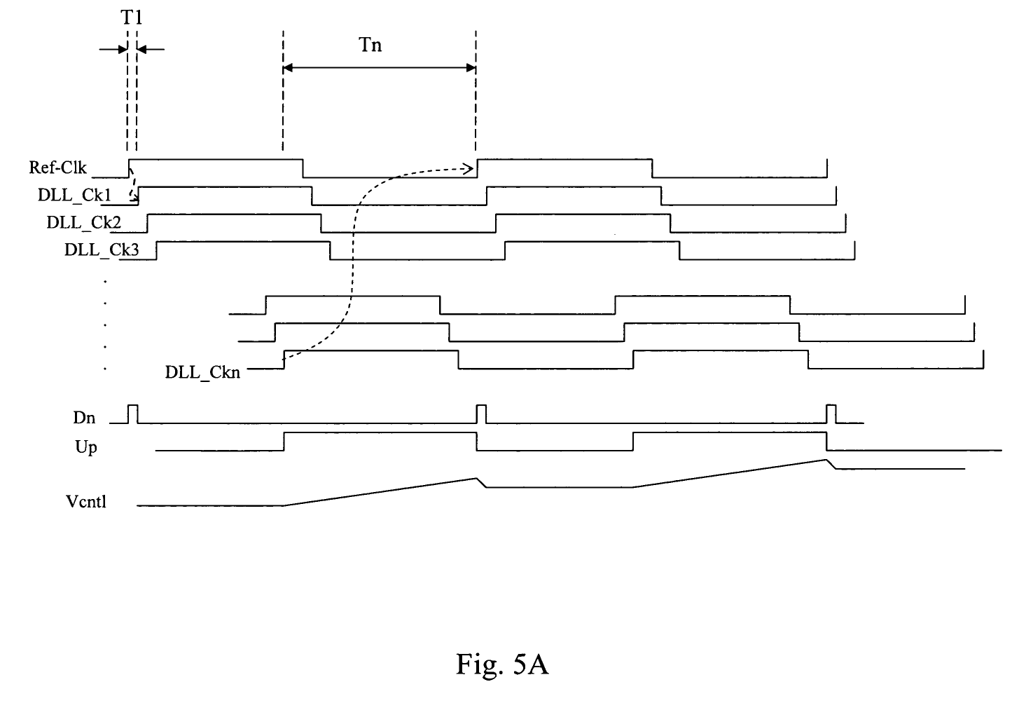

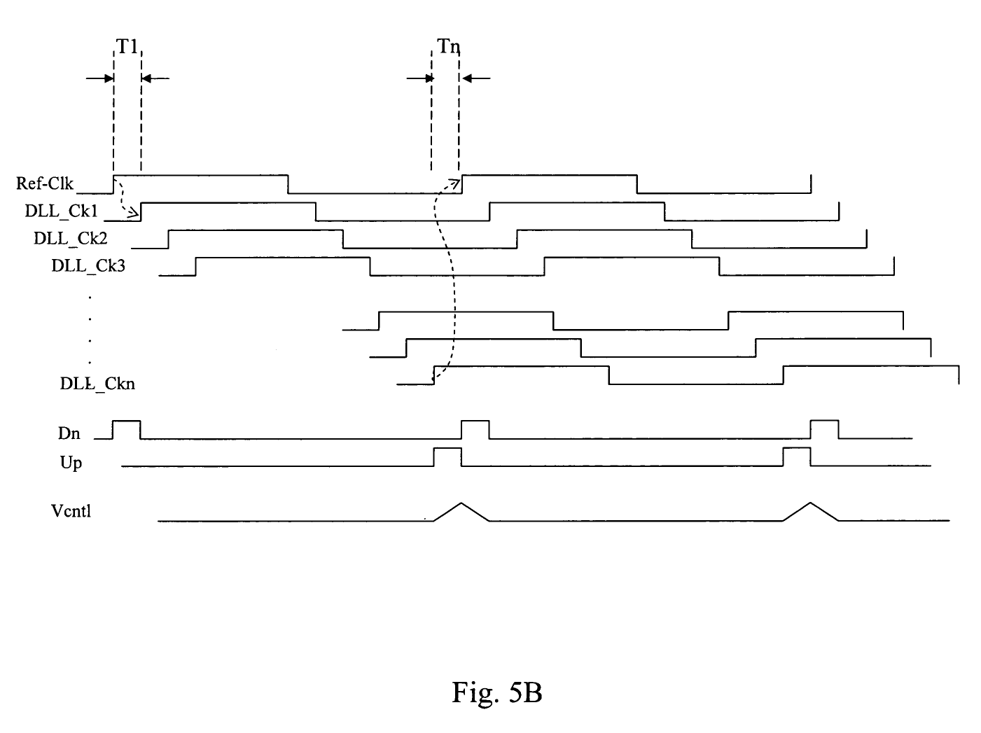

In the above mentioned structure, the first output delay clock signal DLL-Ck1 has a phase difference T1 to the reference clock signal Ref-Clk, and the last output delay clock signal DLL-Ckn has a phase difference Tn to the reference clock signal Ref-Clk. When the DLL starts or restarts, the delay time T_{VCDL} of the VCDL 21 is set in minimum value (T1<Tn) as shown in FIG. 5A. After the difference value between the phase difference T1 and the phase difference Tn, using a voltage regulation way to make T1=Tn as shown in FIG. 5B. The locking range of the DLL is described in equation (2):

T_{VCDL(min)}<T_{CLK}<T_{VCDL(max)} (2)

The operation range of the VCDL 21 can totally operate within the locking range of the DLL.

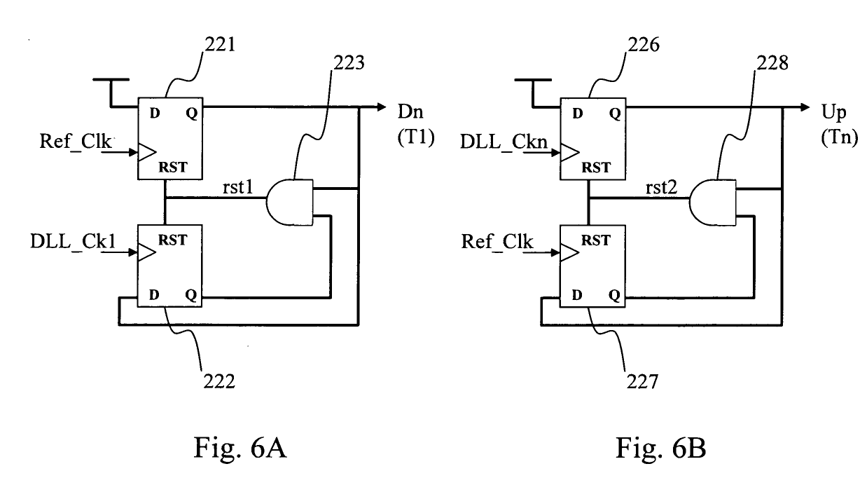

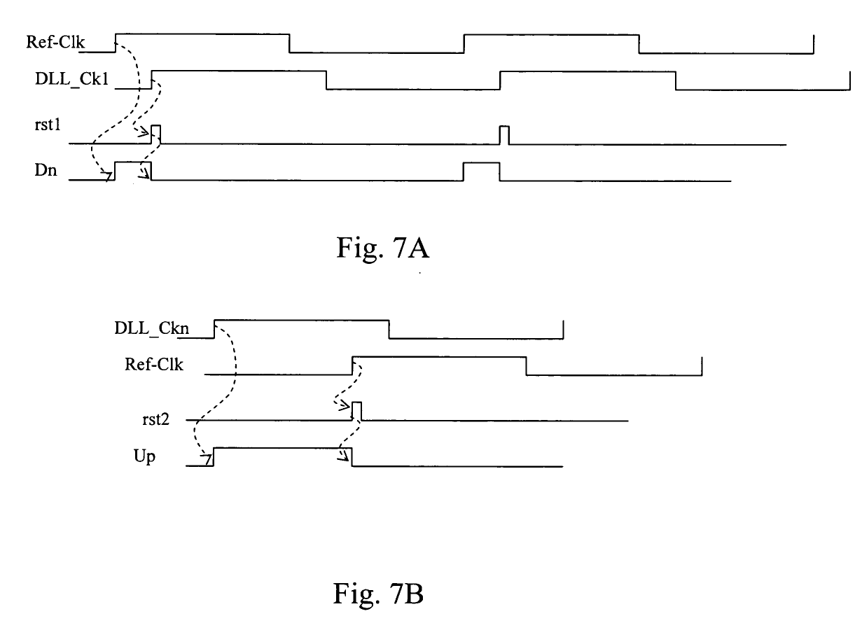

FIG. 6A and FIG. 6B are structural schematic diagrams to demonstrate a 3-edge PD according to one embodiment of the present invention. In FIG. 6A, the D-type flip-flop 221 receives the Ref-Clk and a data signal, and then output a Dn. The D-type flip-flop 222 receives the DLL-Ck1 and the Dn, and then output a signal to the AND logic-gate 223. The AND logic-gate 223 receives the Dn and the digital sampling signal outputted from the D-type flip-flop 222 to decide if it needs to transmit a restart signal rst1 for restarting the D-type flip-flops 221 and 222 or not, wherein the schematic diagram of the signal action is shown in FIG. 7A.

In FIG. 6B, the D-type flip-flop 226 receives the DLL-Ckn and a data signal, and then output an Up. The D-type flip-flop 227 receives the Ref-Clk and the Up, and then output a signal to a AND logic-gate 228. The AND logic-gate 228 receives the Up and the digital sampling signal outputted from the D-type flip-flop 227 to decide if it needs to transmit a restart signal rst2 for restarting the D-type flip-flops 226 and 227 or not, wherein the schematic diagram of the signal action is shown in FIG. 7B.

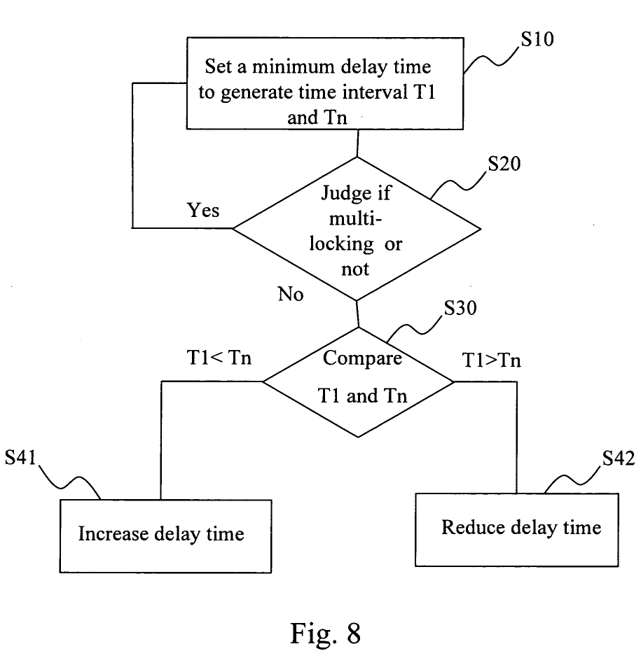

Please refer to FIG. 8, which is a schematic diagram to demonstrate a method to lock clock for a multiphase DLL according to one embodiment of the present invention. Step 10 sets a minimum delay time among a plurality of delay signals existed in the VCDL and arranged according to the time order to make the delay signals have the same delay time between each other, wherein a time interval between a first delay signal and a starting edge of a clock cycle is T1, and a time interval between a last delay signal and a starting edge of the next clock cycle is Tn, and all the delay signals are distributed within a clock cycle. When the circuit starts to operate, T1 is smaller than Tn. Step 20 judges if it is a multi-locking or not, which will go back to Step 10 if it is a multi-locking or go to the next step if it is not a multi-locking. Step 30 compares T1 and Tn to adjust the delay time and so as to make the delay signals fall into a reference clock cycle, and finally lock T1 to equal to Tn. Then, step S41 is executed, it means increasing the delay time to make the delay signals have the same delay time between each other and so as to make the delay signals fall into a reference clock cycle if T1<Tn, or decreasing the delay time to make the delay signals have the same delay time between each other and so as to make the delay signals fall into a reference clock cycle if T1>Tn.

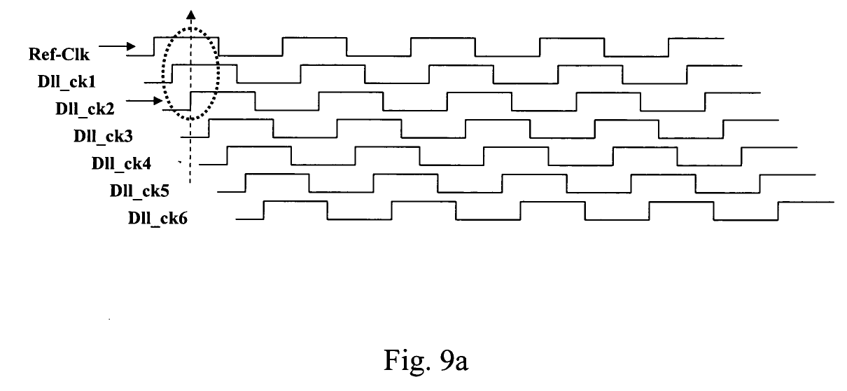

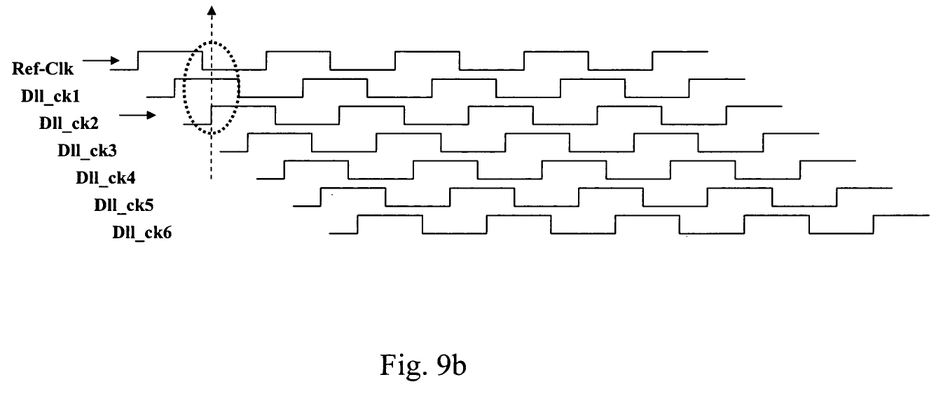

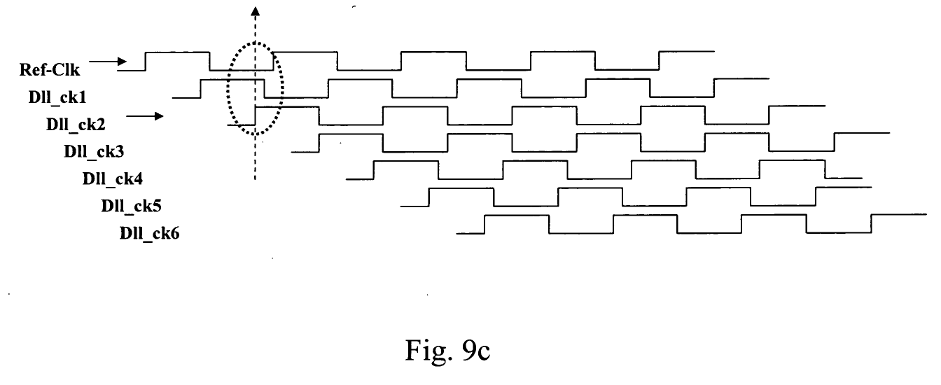

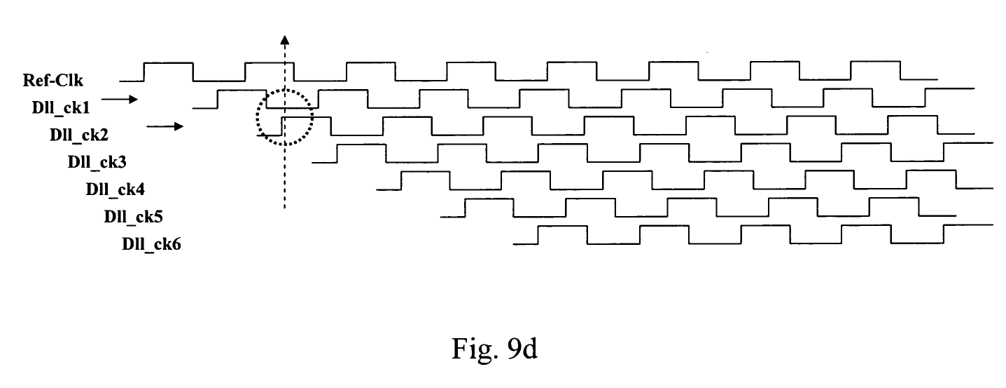

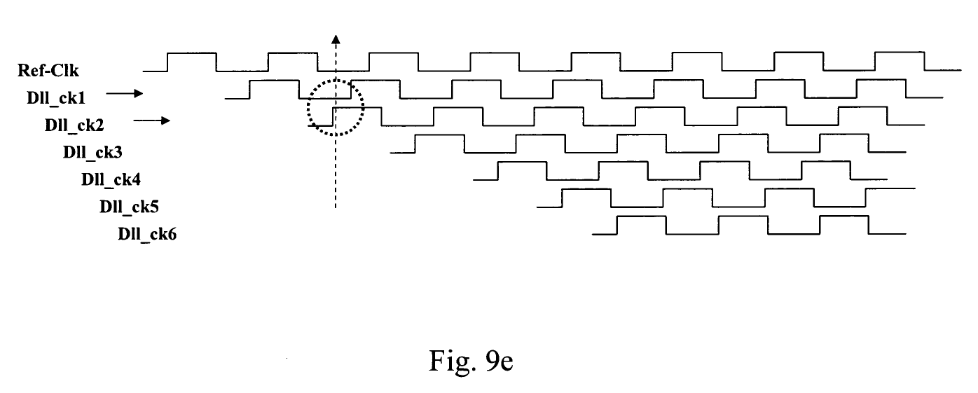

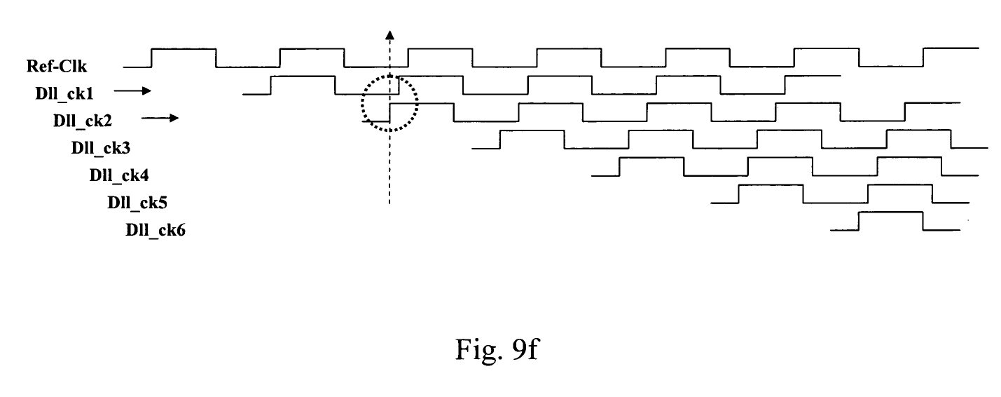

Please refer to FIG. 9a to FIG. 9f, which are schematic diagrams to demonstrate the mechanism for avoiding multi-locking according to one embodiment of the present invention. When the circuit operates, several delay clock signals Dll_ck1, Dll_ck2, Dll_ck3, Dll_ck4, Dll_ck5 and Dll_ck6 are generated after a reference clock signal Ref_Clk is received by the VCDL. When the frequency of the clock signal changes into B from A to make the circuit work normally and lock in a clock cycle, three adjacent clock signals are utilized to do the judgments which are described in the following.

Among the three adjacent clock signals Ref_Clk, Dll_ck1 and Dll_ck2, if the value for the rising edge of the Dll_ck2 sampling Ref_Clk equals to 0, it represents the 2nd or the 3rd cycle is locked as shown in FIG. 9b to FIG. 9c. Otherwise, if the value for the rising edge of the Dll_ck2 sampling Dll_ck1 equals to 0, it represents the 4th, 5th or 6th cycle is locked as shown in FIG. 9d, FIG. 9e and FIG. 9f, which needs to reset the circuit. If the value for the rising edge of the Dll_ck2 sampling Ref_Clk equals to 1, it represents the 1st, 4th or the 5th cycle is locked. Otherwise, if the value for the rising edge of the Dll_ck2 sampling Dll_ck1 equals to 1, it represents the 1st, 2nd or 3rd cycle is locked, and the circuit is normal if the 1st cycle is locked that the delay clock signals fall into a reference clock cycle as shown in FIG. 9a.

According to the aforementioned description, the judgment can be made by inputting the values of the rising edge of the Dll_ck2 sampling Ref_Clk and Dll_ck1 into a logic circuit (not shown in the figure).

To sum up, the multiphase DLL with a 3-edge PD having phase difference and frequency difference of the present invention is advantageous to the whole PLL, which can maximize the wide-clock width of the operation range.

The foregoing descriptions of specific embodiments of the present invention have been presented for purposes of illustrations and description. They are not intended to be exclusive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to particular use contemplated. It is intended that the scope of the invention be defined by the Claims appended hereto and their equivalents.

What is claimed is:

1. A multiphase Delay-Lock Loop (DLL) for wide-range operation, comprising:
a Voltage-Controlled Delay Line (VCDL) to receive a reference clock signal to generate a plurality of delay clock signals, wherein the delay clock signals comprise a first delay clock signal and a second delay clock signal;
a 3-edge Phase Detector (PD) to generate a set of pulse signals according to the reference clock signal, the first delay clock signal and the second delay clock signal;
a charge pump (CP) to receive the pulse signals and output a current control signal; and an Loop Filter (LF) to receive the current control signal and output a control voltage; and
an Loop Filter (LF) to receive the current control signal and output a control voltage, wherein a delay time is adjusted by the VCDL according to the control voltage.

2. The multiphase DLL for wide-range operation according to claim 1, wherein the first delay clock signal has a first phase difference to the reference clock signal, and the second delay clock signal has a second phase difference to the reference clock signal, the second delay clock signal is larger than the first delay clock signal when the multiphase DLL begins a restart operation.

3. The multiphase DLL for wide-range operation according to claim 2, wherein the VCDL is used to adjust the delay time to make the second phase difference equal to the first phase difference when the multiphase DLL completes locking.

4. The multiphase DLL for wide-range operation according to claim 1, wherein the set of pulse signals comprises an up signal and a down signal, and the 3-edge PD comprises:
a first comparison circuit to receive the reference clock signal and the first delay clock signal to generate the down signal; and
a second comparison circuit to receive the reference clock signal and the second delay clock signal to generate the up signal.

5. The multiphase DLL for wide-range operation according to claim 1, wherein the VCDL comprises one to N sequentially connected delay elements, and the first delay clock signal is outputted from the first delay element and the second delay clock signal is outputted from the Nth delay element.

6. The multiphase DLL for wide-range operation according to claim 1, wherein the LF is a capacitor.

7. A 3-edge PD to increase an operation range of a clock width for a multiphase DLL, comprising:
a first comparison circuit to receive the reference clock signal and a first delay clock signal to generate a first pulse signal, wherein the first comparison circuit comprises:
a first flip-flop to receive a data signal and the first pulse signal;
a second flip-flop to receive the first delay clock signal and the first pulse signal to output a first digital sampling signal; and
a first AND logic-gate connected with the first flip-flop and the second flip-flop to receive the first pulse signal and the first digital sampling signal and transmit a restart signal to the first flip-flop and the second flip-flop after a calculation; and
a second comparison circuit to receive the reference clock signal and a second delay clock signal to generate a second pulse signal, wherein the second comparison circuit comprises:
a third flip-flop to receive a data signal and the second pulse signal;
a fourth flip-flop to receive the second delay clock signal and the second pulse signal to output a second digital sampling signal; and
a second AND logic-gate connected with the third flip-flop and the fourth flip-flop to receive the second pulse signal and the second digital sampling signal and transmit a restart signal to the third flip-flop and the fourth flip-flop after a calculation.

8. The 3-edge PD according to claim 7, wherein the first delay clock signal and the second delay clock signal are generated by a VCDL.

9. The 3-edge PD according to claim 8, wherein the VCDL comprises one to N sequentially connected delay elements, and the first delay clock signal is outputted from the first delay element and the second delay clock signal is outputted from the Nth delay element.

10. The 3-edge PD according to claim 7, wherein the first delay clock signal has a first phase difference to the reference clock signal, and the second delay clock signal has a second phase difference to the reference clock signal, the second delay clock signal is larger than the first delay clock signal when the multiphase DLL begins a restart operation.

11. The 3-edge PD according to claim 7, wherein a set of pulse signals comprises an up signal and a down signal.

12. A method to lock clock for a multiphase DLL with wide-range operation, comprising:
setting a minimum delay time among a plurality of delay signals existed in the VCDL and arranged according to the time order to make the delay clock signals have the same delay time between each other, wherein a time interval between a first delay signal and a starting edge of a clock cycle is T1, and a time interval between a second delay signal and a starting edge of a clock cycle is Tn;
comparing T1 and Tn to adjust the delay time and so as to make the delay clock signals fall into a reference clock cycle; increasing the delay time to make the delay clock signals have the same delay time between each other and so as to make the delay clock signals fall into a reference clock cycle if T1<Tn; and
increasing the delay time to make the delay clock signals have the same delay time between each other and so as to make the delay clock signals fall into a reference clock cycle if T1<Tn; and
decreasing the delay time to make the delay clock signals have the same delay time between each other and so as to make the delay clock signals fall into a reference clock cycle if T1>Tn.

13. The method to lock clock for a multiphase DLL with wide-range operation according to claim 12, wherein T1 is smaller than Tn at an initial starting time.

14. The method to lock clock for a multiphase DLL with wide-range operation according to claim 12, wherein the making the delay clock signals have the same delay time between each other further comprises setting the delay clock signals within a reference clock cycle.

15. The method to lock clock for a multiphase DLL with wide-range operation according to claim 12, wherein the adjusting the delay time and so as to make the delay clock signals fall into a reference clock cycle further comprises locking T1=Tn finally.

16. The method to lock clock for a multiphase DLL with wide-range operation according to claim 12, further comprising judging if the delay clock signals fall into a reference clock cycle or not, and restarting a circuit if not.

17. The method to lock clock for a multiphase DLL with wide-range operation according to claim 16, wherein the judging if the delay clock signals fall into a reference clock cycle or not further comprises:
judging if a reference clock signal changes or not;
acquiring three adjacent clock signals including a first signal, a second signal and a third signal if yes;
using the third signal to sample the first signal, and resetting the circuit if it is zero; and
using the third signal to sample the second signal, and resetting the circuit if it is zero.

18. The method to lock clock for a multiphase DLL with wide-range operation according to claim 17, wherein the first signal is the reference clock signal.

19. The method to lock clock for a multiphase DLL with wide-range operation according to claim 16, wherein the judging if the delay clock signals fall into a reference clock cycle or not further comprises:
acquiring three adjacent clock signals including a first signal, a second signal and a third signal;
using the third signal to sample the first signal, and resetting the circuit if it is zero; and
using the third signal to sample the second signal, and resetting the circuit if it is zero.

20. The method to lock clock for a multiphase DLL with wide-range operation according to claim 19, wherein the first signal is the reference clock signal.
